(19) United States
(12) Patent Application Publication
(10) Pub. No.: US 2010/0326818 A1
(43) Pub. Date: Dec. 30, 2010

(54) METHOD OF MANUFACTURING SEMICONDUCTOR DEVICE AND SPUTTERING APPARATUS

(75) Inventors: Manabu Ikemoto, Sagamihara-shi (JP); Nobuo Yamaguchi, Tokyo (JP); Kimiko Mashimo, Tokyo (JP); Kazuaki Matsuo, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/842,732

(22) Filed: Jul. 23, 2010

Related U.S. Application Data
(63) Continuation of application No. PCT/JP2009/068579, filed on Oct. 29, 2009.

(30) Foreign Application Priority Data
Mar. 30, 2009 (JP) 2009-081834

(51) Int. Cl. C23C 14/35; C23C 14/34

(52) U.S. Cl. 204/192.17; 204/192.15; 204/298.07

(57) ABSTRACT

The invention provides a method of manufacturing a semiconductor device and a sputtering apparatus which improve the composition of a film formed by a metal and a reactive gas without increasing the number of steps. An embodiment includes the steps of: placing a substrate on a substrate holder in a process chamber; and sputtering a target in the process chamber by applying electric power thereto while feeding a first reactive gas and a second reactive gas having higher reactivity than that of the first reactive gas into the process chamber, to form a film containing a target material on the substrate. The step of forming a film is conducted by feeding at least the first reactive gas from a first gas feed opening formed near the target, and by feeding the second reactive gas from a second gas feed opening formed at a position with the distance from the target larger than that of the first gas feed opening.

### CROSS-REFERENCES TO RELATED APPLICATIONS

This application is a continuation application of International Application No. PCT/JP2009/068579, filed on Oct. 29, 2009, the entire contents of which are incorporated by reference herein.

This application also claims the benefit of priority from Japanese Patent Application No. 2009-081834 filed Mar. 30, 2009, the entire contents of which are incorporated herein by reference.

### TECHNICAL FIELD

The present invention relates to a method of manufacturing a semiconductor device used for manufacturing a semiconductor element and the like, and to a sputtering apparatus.

### BACKGROUND ART

Oxynitride film containing metal is used in wide application fields as dielectric and electrode in a semiconductor element. For example, TiON has long been used as a contact-barrier layer owing to the high barrier performance. As for the high permittivity film which is adopted in a large quantity along with the progress of refinement of semiconductor device in recent years, there has been increasing the interest in oxynitride film containing Hf and Zr, for example, owing to the high heat resistance. As the gate electrode, polycrystalline silicon is conventionally used. The polycrystalline silicon unavoidably induces depletion because the material is a semiconductor. To this point, Patent Document 1 discloses the use of an oxynitride film such as Ti which is a metal, having excellent heat resistance, and providing good work function.

There are two methods of manufacturing that type of film containing an oxynitrided metal: the physical method and the chemical method. As the method of industrially practical one, the physical method includes the sputtering method, and the chemical method includes the CVD method including the ALD method. The CVD method uses an organic metal compound as the raw material gas in many cases, and thus there arises a problem that carbon likely enters the formed film. The raw material gas used in the CVD method is toxic in many cases, thus requiring detoxication of unused raw material and of byproducts. The film-forming by the sputtering method is advantageous in view of device performance and cost because of being free from the problems of CVD method, such as carbon inclusion and detoxication of unused raw material and of byproducts.

For the case of manufacturing a metal-containing oxynitride film by the sputtering method, there are largely three applicable methods:

(1) The method of forming a metal oxynitride film using a metal target to form the film by the reactive sputtering method in an atmosphere containing oxygen and nitrogen;
(2) The method of forming a metal oxynitride film using the sputtering method applying a dielectric target such as metal oxide target and metal nitride target; and
(3) The method of forming a metal oxynitride film or a metal-containing oxynitride film by forming a metal or a metal-containing film on the substrate by the sputtering method, and then by applying the oxynitridation treatment to thus formed metal or metal-containing film.

As an example of the first method (1), Patent Document 2 discloses a method of forming a TiON film as the thin-film resister using Ti as a target in an atmosphere containing a gas containing water, oxygen-element such as oxygen gas, and nitrogen gas. Patent Document 1 discloses a method of forming Ti, Ta, and other oxynitride film as the electrode film on the high permittivity film using Ti, Ta, and other metal as the target in an atmosphere containing nitrogen and oxygen. Patent Document 3 discloses a method of forming ZrON or HfON using Zr or Hf as the target in an atmosphere of mixture of oxygen and nitrogen. As for the apparatus which can form those types of oxynitride films, Patent Document 4 discloses a reactive sputtering apparatus which can form a film on a substrate by feeding a reactive gas near the substrate, and by feeding an inert gas near the target, thus preventing the formation of compound generated by a reaction between the target material and the reactive gas on the surface of the target, and thereby suppressing the decrease in the thin-film forming rate.

Regarding the second method (2), Patent Document 5 discloses a method of forming a TiON film using titanium oxide as the target and applying, for example, nitrogen gas or a mixture of inert gas with nitrogen gas.

The third method (3) forms a metal film or a metal-containing film, followed by oxynitridation. As an example of the third method, Patent Document 6 discloses the formation of a TiON film by forming a TiN film, and then by bringing the TiN film to react with an excited oxygen. Another example of the third method is disclosed by Patent Document 7, in which ZrN, ZrSiN, HfN or HfSiN is formed by the reactive sputtering of a mixed gas of Ar and N₂, and then oxidation is given to form ZrON, ZrSiON, HfON and HfSiON, respectively.

### DOCUMENTS IN THE RELATED ART

### Patent Documents

[Patent Document 1] Japanese Patent Laid-Open No. 2007-173796

[Patent Document 2] Japanese Patent Laid-Open No. 2000-294738

[Patent Document 3] Japanese Patent Laid-Open No. 2000-58832

[Patent Document 4] Japanese Patent Laid-Open No. 5-65642

[Patent Document 5] Japanese Patent Laid-Open No. 11-286773

[Patent Document 6] Japanese Patent Laid-Open No. 5-6825

[Patent Document 7] Japanese Patent Laid-Open No. 2002-314067

### SUMMARY OF INVENTION

The first method is most preferable among above three methods because of allowing forming the metal oxynitride film in a single step and because of high film-forming speed owing to the use of metal target. If, however, the first method is to be applied for forming the gate electrode film, the reaction needs, as disclosed in Patent Document 1, to use oxygen fed from an oxygen-leak valve, or to use oxygen left in the reaction chamber before sputtering in a vacuum of about 1×10⁻⁴ Torr (Patent Document 1 describes as the background pressure). The requirement comes from that oxygen shows higher reactivity than that of nitrogen, and that, to attain a desired composition, the partial pressure of oxygen or oxygen-containing gas has to be controlled at a very low pressure level compared with that of nitrogen. That type of control is, however, very difficult, and the method is not suitable for the mass-production method for the semiconductor elements.

The second method is advantageous to form a metal oxynitride film in a single step, similar to the first method. However, the second method has a problem of slow film-forming speed owing to the use of dielectric target.

The third method raises a problem of increase in the number of steps, (requiring more than one step for forming film), which increases the number of chambers, to increase the production cost.

As described above, on forming an oxynitride film, it was difficult to increase the controllability of film composition without increasing the number of steps, which increases the cost.

To this point, an object of the present invention is to provide a method of manufacturing a semiconductor device and to provide a sputtering apparatus, with improved controllability of composition of metal and reactive gas without increasing the number of steps.

To achieve the above object, the present invention may provide a method of manufacturing a semiconductor device comprising the steps of: placing a substrate on a substrate holder in a process chamber; and sputtering a target in the process chamber by applying electric power thereto while feeding a first reactive gas and a second reactive gas having higher reactivity than that of the first reactive gas into the process chamber, to form a film containing a target material on the substrate, wherein the step of forming a film is conducted by feeding at least the first reactive gas from a first gas feed opening formed near the target, and by feeding the second reactive gas from a second gas feed opening formed at a position with the distance from the target larger than that of the first gas feed opening.

The present invention may provide a sputtering apparatus comprising: a process chamber; a target holder provided in the process chamber for holding a target; a voltage-supply mechanism for applying a specified voltage to the target holder; a magnetic-field forming mechanism to form a magnetic field near the target holder; a first gas feed opening formed near the target holder for feeding a first reactive gas into the process chamber; and a second gas feed opening formed at a position with the distance from the target holder larger than that of the first gas feed opening, for feeding a second reactive gas having reactivity higher than that of the first reactive gas, into the process chamber.

According to the present invention, the method of manufacturing a semiconductor device using a target and a plurality of reactive gases, (for example, the reactive sputtering method), can form a film with improved controllability of composition of metal and reactive gas without increasing the number of steps.

### BRIEF DESCRIPTION OF THE DRAWINGS

FIG. 1 is a schematic cross sectional view of a reactive sputtering apparatus of the present invention.

FIG. 2 is a detailed vertical cross sectional view near a first gas feed opening 15.

FIG. 3 is a detailed lateral cross sectional view near the first gas feed opening 15 and a second gas feed opening 17.

FIG. 4 is a detailed vertical cross sectional view near the second gas feed opening.

FIG. 5 is a schematic diagram of a substrate shutter 19 facing a substrate outer cover ring 21.

FIG. 6 is a schematic diagram of the substrate outer cover ring 21 facing the substrate shutter 19.

FIG. 7 is a diagram illustrating the film structure of a semiconductor device of gate-stack structure.

FIG. 8 is a schematic diagram illustrating an example of a cluster-type manufacturing apparatus used in the manufacturing step of the present invention.

FIG. 9 is a process flow diagram illustrating an example of the method of manufacturing a semiconductor device of gate-stack structure given in FIG. 7.

FIG. 10 is a graph showing an evaluation result of an oxygen concentration distribution in the depth direction of the gate-stack structure using XPS.

FIG. 11 is a diagram showing the procedure of forming a gate-electrode film using a sputtering chamber 1.

FIG. 12 is a process flow diagram illustrating another method of manufacturing a semiconductor device having the gate-stack structure given in FIG. 7.

### DESCRIPTION OF EMBODIMENTS

The present invention will be described in detail exemplifying preferred embodiments referring to the drawings. The structural elements described in the embodiments are given only for examples, and the technological scope of the present invention is defined in claims, and is not limited to the individual embodiments.

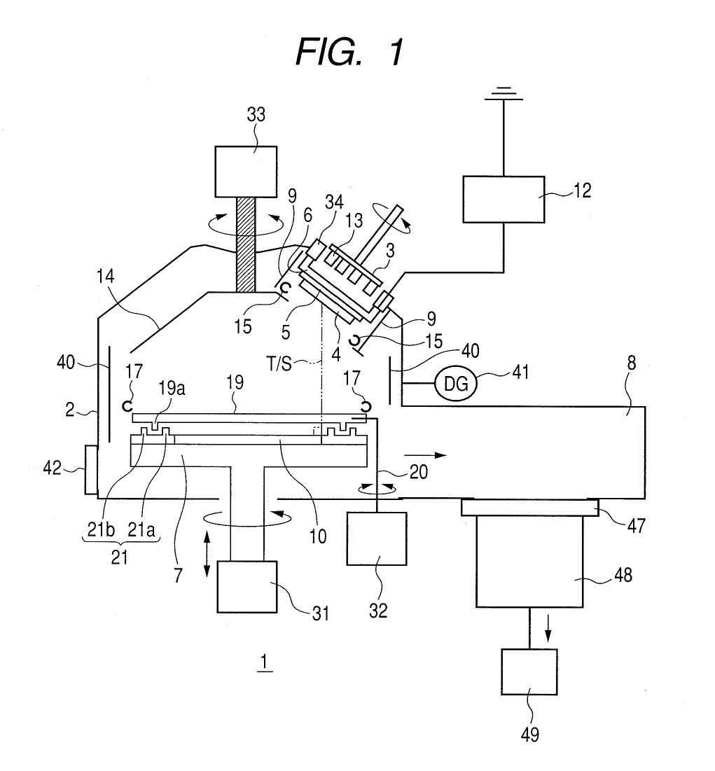

The description begins with the entire structure of a sputtering film-forming apparatus 1 referring to FIG. 1. FIG. 1 is a schematic view of the sputtering apparatus 1 according to the embodiments of the present invention. The sputtering film-forming apparatus 1 includes a vacuum chamber 2 which can be evacuated, an exhaust chamber 8 provided adjacent to the vacuum chamber 2 via an exhaust opening, and an exhaust apparatus to evacuate the vacuum chamber 2 via the exhaust chamber 8. The exhaust apparatus has a turbo-molecular pump 48. The turbo-molecular pump 48 in the exhaust apparatus is further connected to a dry pump 49. The exhaust apparatus is positioned beneath the exhaust chamber 8 to minimize the foot-print (occupied area) of entire apparatus.

The vacuum chamber 2 is provided with a target holder 6 therein to hold a target 4 via a back plate 5. Near the target holder 6, a target shutter 14 is disposed so as to cover the target holder 6. The target shutter 14 has a structure of rotary shutter. The target shutter 14 functions as a shielding member so as to establish a closed state (shielding state) between the substrate holder 7 and the target holder 6 or to establish an open state (retracting state) therebetween. The target shutter 14 has a target shutter driving mechanism 33 to conduct open/close of the target shutter 14. In a space between the target holder 6 and the target shutter 14 and along the periphery of the target holder 6, a chimney 9 which is a cylindrical shield is attached so as to enclose the periphery of the target holder 6. A magnetron discharge space in front of the sputtering face of the target 4 attached to the target holder 6 is surrounded by the chimney 9, and thus, when the shutter is in open state, the space opens to the opening part of the target shutter 14.

At rear side of the target 4, viewed from the sputtering face, there are arranged magnets 13 to execute the magnetron sputtering. The magnets 13 are supported by a magnet holder 3, and are rotatable driven by a magnet holder rotating mechanism (not shown). To uniformize the erosion of the target, the magnets 13 keep rotating during the discharge period.

The target 4 is positioned obliquely upward with respect to the substrate 10, (at an offset position). That is, the center of the sputtering face of the target 4 is positioned deviating by a specified distance from the normal line of the substrate 10 at the center thereof. The target holder 6 is connected to a power source 12 which applies electric power for sputtering discharge. When the power source 12 applies voltage to the target holder 6, discharge begins and the sputtering particles are deposited on the substrate. The distance between the intersection where a normal line of a plane including the upper face of the substrate holder 7, passing through the center of the face of the target 4, intersects with the plane, and the center of the face of the target 4 is defined as a T/S distance (refer to FIG. 1). The embodiment adopts 240 mm of T/S distance. Although according to the embodiment, the film-forming apparatus 1 shown in FIG. 1 has a DC power source, the power source is not limited to that DC power, and, for example, an RF power source can be applied. When the RF power source is adopted, a matching box is required to be inserted between the power source 12 and the target holder 6.

The target holder 6 is insulated from the vacuum chamber 2 at a ground potential by an insulator 34. In addition, since the target holder 6 is made of metal such as copper, the target holder 6 acts as an electrode when DC or RF power is applied thereto. The target holder 6 has a water passage (not shown) therein, and can be cooled by cooling water supplied from a water pipe (not shown). The target 4 contains a material component for forming a film on the substrate 10. The target 4 preferably has high purity since the purity affects the purity of the depositing film.

The back plate 5 disposed between the target 4 and the target holder 6 is made of metal such as copper, and holds the target.

The vacuum chamber 2 includes the substrate holder 7 for placing the substrate 10 thereon, a substrate shutter 19 provided between the substrate holder 7 and the target holder 6, and a substrate shutter driving mechanism 32 to drive opening/closing of the substrate shutter 19. The substrate shutter 19 is positioned near the substrate holder 7, and functions as a shielding member so as to establish a closed state for shielding between the substrate holder 7 and the target holder 6 or to establish an open state for opening therebetween.

There is provided a shielding member in a ring shape, (hereinafter referred to as the “substrate outer cover ring 21”), on the face of the substrate holder 7 and at outer edge side (outer peripheral part) in the portion of placing the substrate 10. The substrate outer cover ring 21 prevents sputtering particles from adhering to other portion than the portion of forming a film on the substrate 10 placed on the substrate holder 7. The “other portion than the portion of forming a film” includes not only the front face of the substrate holder 7 covered by the substrate outer cover ring 21 but also the side face and rear face of the substrate 10. The substrate holder 7 has a substrate holder driving mechanism 31 for moving the substrate holder 7 up and down, and for rotating thereof at a specified speed. The substrate holder driving mechanism 31 is able to move the substrate holder 7 up and down, and to fix thereof at an adequate position.

The vacuum chamber 2 includes a first gas feed opening 15 for feeding a first reactive gas into the vacuum chamber 2, a second gas feed opening 17 for feeding a second reactive gas thereinto, and a pressure gauge 41 for measuring the inside pressure of the vacuum chamber 2. The first gas feed opening 15 is connected to a gas-feeding means 501 (to be described later) at least having a pipe for feeding the first reactive gas (such as nitrogen gas), a mass flow controller for controlling the flow rate of the first reactive gas, and valves to shut off and begin the flow of the first reactive gas. The gas-feeing means 501 may have a pressure-reducing valve and a filter, as needed. The first gas feed opening 15 having that structure assures stable flow rate of the gas responding to a command of a controller (not shown). The first gas feed opening 15 is positioned near the target 4. The first gas feed opening 15 allows the first reactive gas to be fed toward the space in front of the target 4 where the magnetron discharge is generated.

From the first gas feed opening 15, a mixed gas of the first reactive gas and an inert gas (such as argon) may be fed.

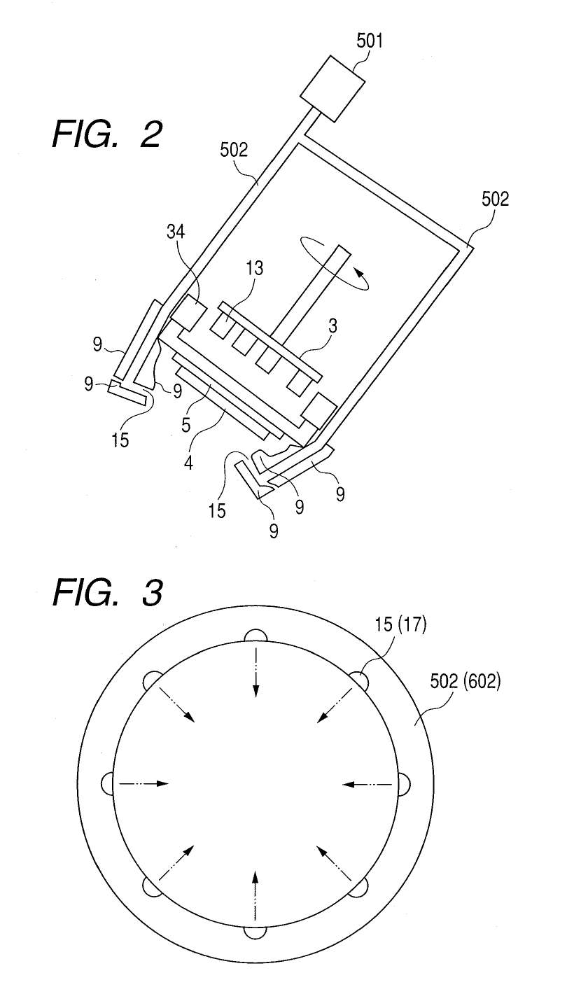

Referring to FIG. 2 and FIG. 3, the detail structure of the first gas feed opening 15 for feeding the reactive gas from near the target will be described below. FIG. 2 illustrates a detailed vertical cross section near the first gas feed opening. The gas-feeing means 501 for supplying the reactive gas (nitrogen gas N₂) and the inert gas (argon gas Ar) is connected to the gas feed opening 15 provided at the front end part of the chimney 9 via a gas feed pipe 502 and the chimney 9. The gas feed opening 15 is formed near the target to discharge the gas toward the center axis of the target. The term “near the target (target holder)” referred to herein means at least a position closer to the target (target holder) side than the intermediate position between the target (target holder) and the substrate. In more detail, the gas feed opening 15 is positioned at the front end part of the chimney 9 as the cylindrical shield apart from the target surface by a specified distance (10 to 200 mm). With the structure, the reactive gas or a mixture of inert gas and reactive gas is fed to a portion where the magnetic flux density of the magnetic components parallel to the target surface in the magnetic field generated by a magnet 13 becomes large and where the magnetic flux density of the parallel components in the magnetic field becomes at least 0.2 mT (millistera) or more. This is because the plasma density increases during processing in the portion of increased magnetic flux density of the parallel components, and thus the fed reactive gas becomes easily activated. According to the embodiment, the magnets 13 correspond to the magnetic field forming mechanism of the present invention. However, the structure is not limited to the above-described embodiment, and for example, the magnetic field can be applied using an electromagnet and the like as the magnetic field forming mechanism.

FIG. 3 illustrates a lateral cross section of the first gas feed opening 15. As shown in FIG. 3, the circular gas feed pipe 502 has a plurality of first gas feed openings 15 arranged in a point-symmetric manner so as to feed the gas uniformly (symmetrically) toward the discharge space in front of the target 4. The gas feed openings 15 having above structure may be a plurality of feed holes on a gas ring or may be a thin slit uniformly opened.

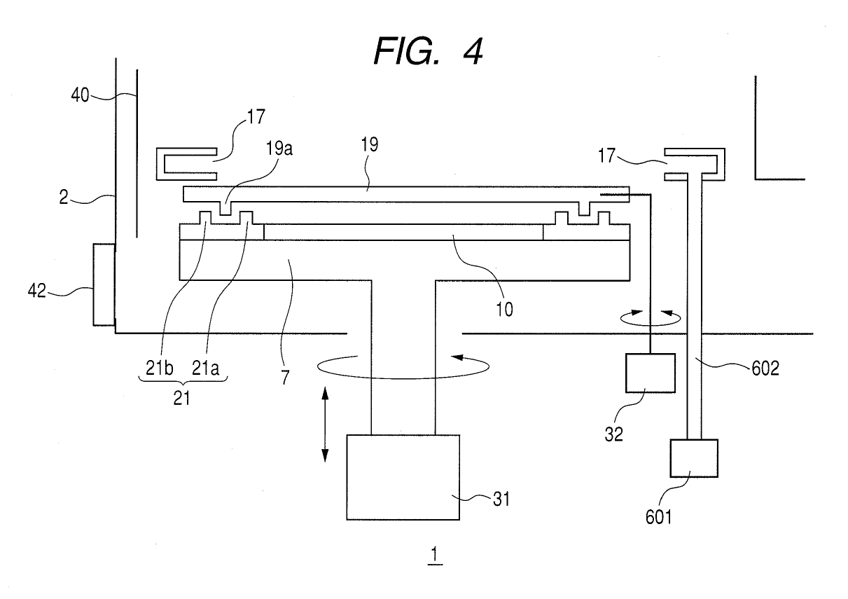

Referring to FIG. 4, the detail structure of the second gas feed opening 17 for feeding a reactive gas from near the substrate holder will be described below. FIG. 4 illustrates a detailed vertical cross section near the second gas feed opening for supplying the second reactive gas (oxygen gas O₂). A gas-feeing means 601 communicates with the gas feed opening 17 formed above the substrate shutter 19 via a gas feed pipe 602. The gas feed opening 17 is positioned so as to feed the gas into the gas chamber toward the substrate. Similar to the first gas feed opening 15 given in FIG. 3, the circular gas feed pipe 602 has a plurality of second gas feed openings 17 arranged in a point-symmetric manner so as to allow feeding the gas uniformly near the substrate.

The gas-feeing means 601 has a mass flow controller for controlling a flow rate of the second reactive gas and valves to shut off and begin the flow of the second reactive gas. The gas-feeing means 601 may have a pressure-reducing valve, a filter, and the like as needed. The second gas feed opening 17 has a structure that assures stable flow rate of the gas responding to a command of a controller (not shown). The second gas feed opening 17 is positioned near the substrate holder 7 which holds the substrate 10. That is, the second gas feed opening 17 is formed at a position with a distance from the target surface larger than that of the first gas feed opening. The second gas feed opening 17 allows the second reactive gas to be fed near the substrate 10 held by the substrate holder 7. The second gas feed opening preferably has a structure to allow the gas to be fed uniformly (symmetrically) toward the deposition face on the front face of the substrate 10. The gas feed openings 17 having above structure may be a plurality of feed holes formed on a gas ring or may be a thin slit uniformly opened thereon.

The first reactive gas is a gas containing at least nitrogen. In an embodiment of the present invention, a mixture of nitrogen gas as the first reactive gas with an inert gas such as argon may be fed from the first gas feed opening 15 to the vacuum chamber 2. The second reactive gas is a gas having higher activity than that of the first reactive gas, and more specifically a gas containing at least oxygen. As described above, the first gas feed opening 15 is formed near the target holder 6 so as to activate the gas having low activity or having low reactivity and to increase the reactivity by the electric power applied to the target holder 6. The term “process gas” referred to herein signifies a general name of the gas supplied into the vacuum chamber 2 during the film-forming treatment, and does not name a specific gas. For example, the process gas includes the first reactive gas, the second reactive gas, and the inert gas.

To the contrary, the reason to locate the second gas feed opening at a position with a distance from the target larger than that of the first gas feed opening 15, that is, to form the second gas feed opening 17 near the substrate holder 7 is to prevent or suppress the excessive activation of the above highly reactive gas by supplying the highly active gas, or highly reactive gas, apart from the target holder 6.

As described above, according to the present invention, the power applied to the target holder 6 for sputtering is utilized to activate the low-reactivity first reactive gas. Moreover, for the high-reactivity second reactive gas, the first gas feed opening 15 is formed near the target holder 6 to suppress the activation by the above power, while the second gas feed opening 17 is formed near the substrate holder 17. That is, arranging the first gas feed opening 15 and the second gas feed opening 17 as described above makes the plasma generated in the target holder 6 act on the first reactive gas to activate thereof, while the second reactive gas not wanted to be excessively activated is suppressed from receiving the action of the plasma coming from the target holder 6.

As a result, even without separately providing the mechanism for activating the first reactive gas, the power supplied to the target holder for sputtering the target 4 allows the first reactive gas to be activated, and therefore efficient film-forming can be performed without increasing the cost. Furthermore, since the second gas feed opening 17 for feeding the second reactive gas having higher reactivity than that of the first reactive gas into the vacuum chamber 2 is positioned apart from the target holder 6 to which the power is supplied, sudden activation of the second reactive gas can be suppressed, and reaction of the second reactive gas can be performed as scheduled, thereby improving the controllability of the formed film composition.

The term “reactive gas” referred to herein signifies a gas which reacts with sputtering particles coming from the target, and reacts with target surface or film formed. The term “near the substrate holder” referred to herein signifies a position at least closer to the substrate holder side than the intermediate position between the target and the substrate holder.

The first reactive gas and the second reactive gas are fed to the vacuum chamber 2 and are used for forming a film. After that, these gases are discharged via the exhaust chamber 8 by the turbo-molecular pump 48 and the dry pump 49 except for a part thereof being used to form the film.

The inside face of vacuum chamber 2 is grounded. On the inside face of vacuum chamber 2 between the target holder 6 and the substrate holder 7, there is provided a grounded cylindrical shield member (shield 40). The term “shield” referred to herein signifies a member which prevents the sputtering particles emitted from the target 4 from directly adhering to the inside face of vacuum chamber 2, and which is formed separately from the vacuum chamber 2 to protect the inside face of the vacuum chamber, allowing exchanging thereof in a regular timing and allowing thereof to be re-used after cleaned.

The exhaust chamber 8 connects the vacuum chamber 2 with the turbo-molecular pump 48. Between the exhaust chamber 8 and the turbo-molecular pump 48, there is provided a main valve 47 for cutting off between the film-forming apparatus 1 and the turbo-molecular pump 48 during maintenance work.

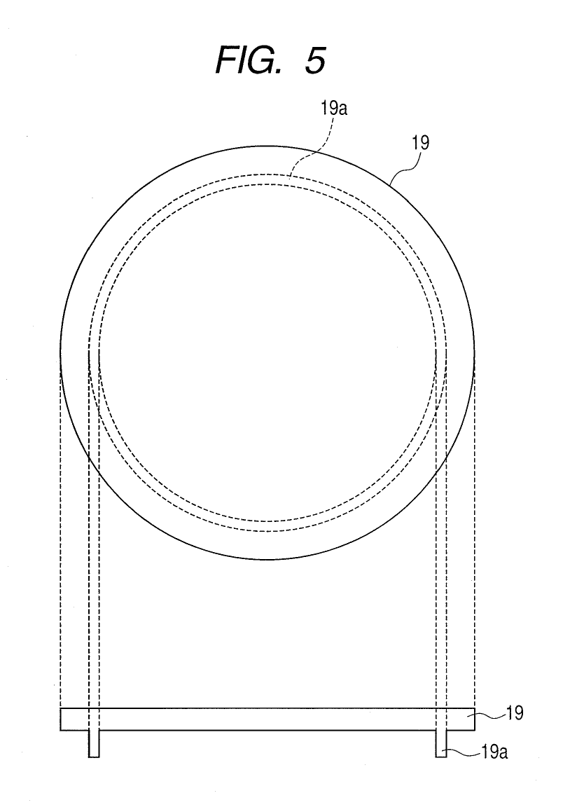

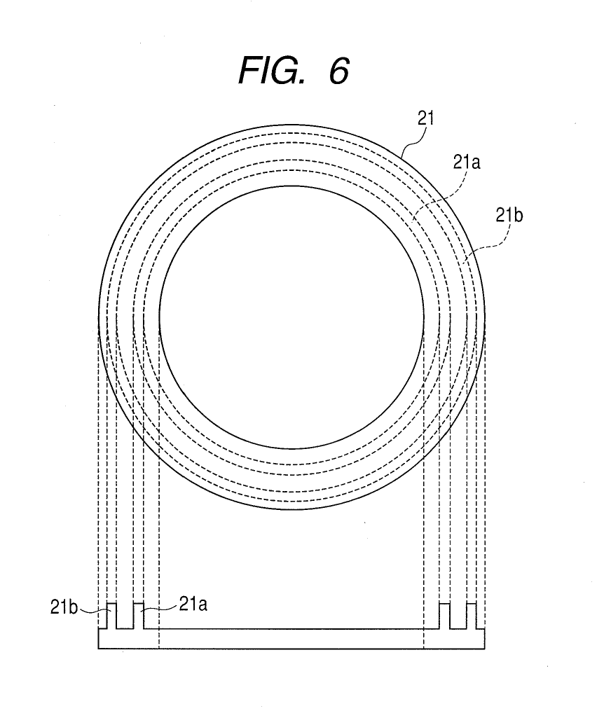

Referring to FIG. 5 and FIG. 6, detail of the shape of the substrate outer cover ring 21 and the substrate shutter 19 will be described. FIG. 6 is a schematic diagram of the substrate outer cover ring 21 facing the substrate shutter 19. The substrate outer cover ring 21 has protrusions in a ring shape extending toward the substrate shutter 19. The substrate outer cover ring 21 is in a ring shape, and concentric circle protrusions 21a and 21b are formed on a surface of the substrate outer cover ring 21 facing the substrate shutter 19.

FIG. 5 is a schematic diagram of the substrate shutter 19 facing the substrate outer cover ring 21. The substrate shutter 19 has a protrusion in a ring shape extending toward the substrate outer cover ring 21. On the face of the substrate shutter 19 facing the substrate outer cover ring 21, a protrusion part (protrusion 19a) is formed. The circumference becomes large in an order from the protrusion 21a, the protrusion 19a, to the protrusion 21b.

At an ascending position of the substrate holder driven by the substrate holder driving mechanism 31, the protrusion 19a and the protrusions 21a and 21b fit together in a non-contact state. Alternatively, at a descending position of the substrate shutter 19 driven by the substrate holder driving mechanism 32, the protrusion 19a and the protrusions 21a and 21b fit together in a non-contact state. In these cases, into a concave formed by the plurality of protrusions 21a and 21b, another protrusion 19a fits in a non-contact state.

The quantity of plurality of protrusions is not limited to the one described above, and for example, one or more protrusions formed on the substrate outer cover ring and two or more protrusions formed on the substrate shutter may be applied, and inversely, two or more protrusions formed on the substrate shutter and one or more protrusions formed on the substrate outer cover ring may be applied. With the structure to form labyrinth using these protrusions, adhesion of sputtering particles to the substrate placing face of the substrate holder can be prevented.

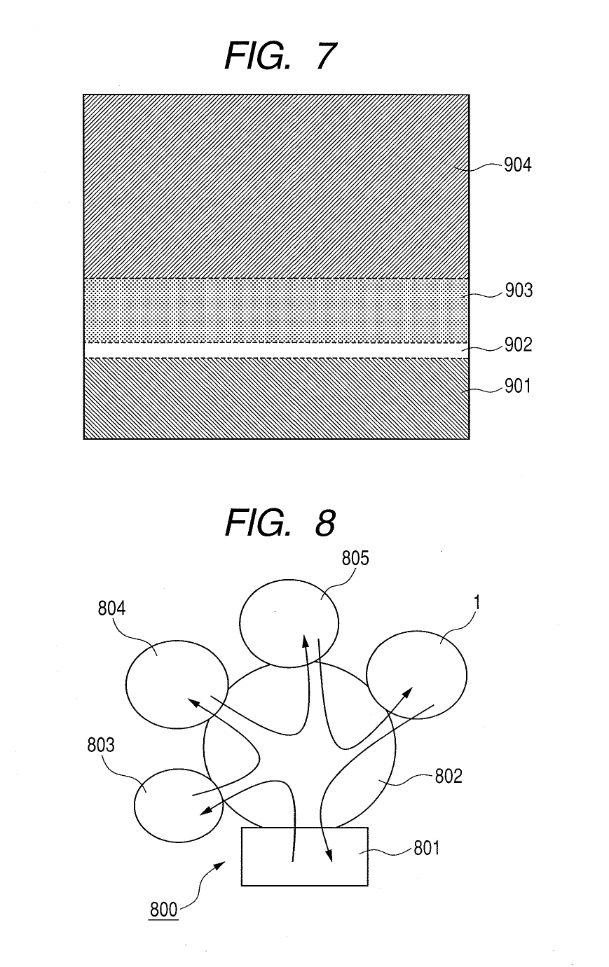

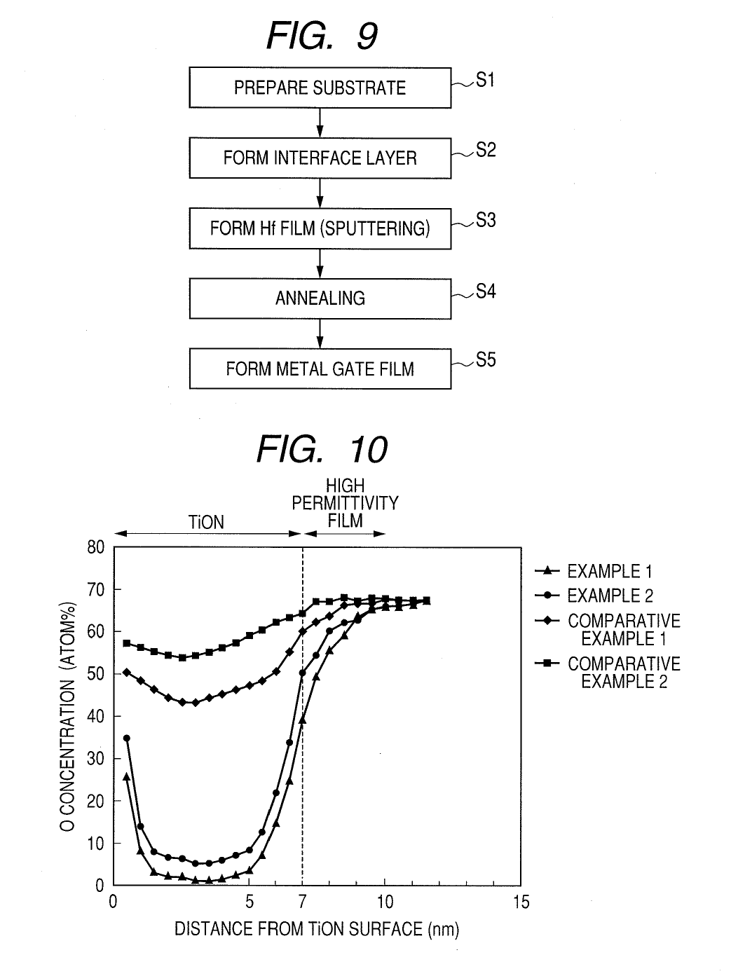

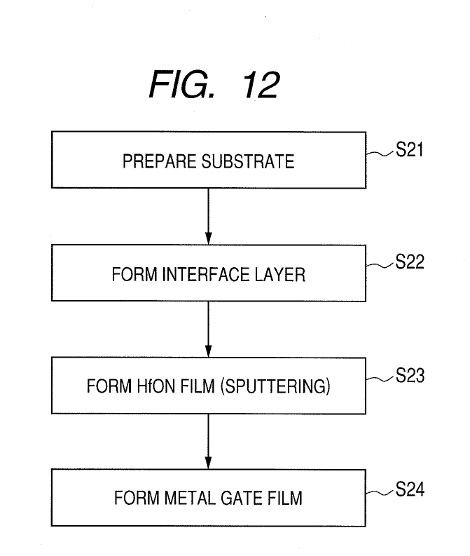

Next, the description will be given on the method of manufacturing a semiconductor device according to an embodiment of the present invention, referring to FIG. 7, FIG. 8, FIG. 9 and FIG. 12. The embodiment deals with a manufacturing step of oxynitride film containing metal.

FIG. 7 illustrates a cross section of an exemplary semiconductor device of gate-stack structure fabricated by the manufacturing steps. The semiconductor device given in FIG. 7 has a structure of laminating an interface layer 902, a high permittivity film 903, and a gate electrode 904 on a substrate 901.

Silicon Si is used as the semiconductor substrate 901, however the material of which is not limited to silicon, and there may be used a semiconductor material such as Ge, SiGe, and SiC, or a silicon-on-insulator structure. A preferred material of the interface layer 902 is silicon oxide, SiO₂, though not limited thereto. The film thickness of the interface layer 902 is in a range from 0.1 to 5 nm. The high permittivity film 903 is an oxide, a nitride, an oxynitride, or a combination thereof, such as HfO₂, ZrO₂, Al₂O₃, TiO₂, La₂O₃, SrTiO₃, LaAlO₃, Y₂O₃, Ga₂O₃, GdGaO, HfON, or a mixture thereof. The film thickness of the high permittivity film is in a range from 0.5 to 3 nm. As for the gate electrode 904, titanium oxynitride TiOₓN_{y} is used, where 5≦X≦40 and 5≦Y≦40. Although the embodiment uses a titanium oxynitride, the material is not limited thereto, and for example, Si, Hf, Al, La, Ta, and other metals can be used to form an oxynitride film. The numerals used to express the composition herein are based on the atomic percentage (at %).

FIG. 8 is a schematic diagram illustrating an example of cluster-type manufacturing apparatus used in the manufacturing steps of the present invention.

A manufacturing apparatus 800 has a transfer chamber 802 at center thereof. In peripheral area of the transfer chamber 802, there are arranged a load-lock chamber 801, an oxidation process chamber 803, a sputtering chamber 804, a heating chamber 805, and the sputtering chamber (sputtering apparatus) 1 characteristic in the present invention, via the respective gate valves. The transfer chamber 802 has a transfer robot (not shown) capable of transferring the substrate among chambers. Each of the chambers 801, 802, 803, 804, 805 and 1 has exhaust means which can evacuate the chamber to a vacuum. Since individual chambers are connected with each other in a vacuum via each gate valve, the entire treatment steps can be conducted in a vacuum without exposing the substrate to atmospheric air.

### Example 1

FIG. 9 is the process flow diagram illustrating the method of manufacturing the semiconductor device of gate-stack structure given in FIG. 7.

In Step 1, the semiconductor substrate 901 is carried-in to the manufacturing apparatus 800 from the load-lock chamber 801. In Step 2, the transfer robot of the transfer chamber 802 transfers the semiconductor substrate 901 from the load-lock chamber 801 to the oxidation process chamber 803 without exposing the substrate 901 to atmospheric air, where the interface layer 902 made of silicon oxide, SiO₂, is formed on the surface of the semiconductor substrate 901 by the thermal oxidation process. The process is, however, not limited to the thermal oxidation, and there can be applied a film-forming process such as ALD, or a plasma oxidation process.

In Step 3 and Step 4, the high permittivity film 903 is formed on the upper face of the interface layer 902. First, in Step 3, the transfer robot carries-in the semiconductor substrate 901 on which the interface layer 902 was formed to the sputtering chamber 804, where a metal layer made of Hf is formed on the upper face of the interface layer 902 using the physical vapor-deposition method such as sputtering. In Step 4, the transfer robot carries-in the semiconductor substrate 901 on which the metal layer was formed from the sputtering chamber 804 to the heating chamber 805 without exposing the substrate 901 to atmospheric air, thus executing the thermal processing. The thermal processing induces a thermal reaction between the metal layer and the interface layer 902, thereby forming hafnium oxide, HfO₂, as the high permittivity film 903.

In Step 5, the transfer robot carries-in the semiconductor substrate 901 on which the high permittivity film 903 was formed to the sputtering chamber 1, thus forming the gate electrode film 904 on the upper face of the high permittivity film 903 using the reactive sputtering method.

In concrete terms, in Step 5, Ti was prepared as the material of the target 4, and a TiON film (gate electrode film 904) was formed using the sputtering method in an atmosphere of: argon gas; nitrogen gas as the first reactive gas; and oxygen gas as the second reactive gas. Argon gas which is one of the process gases and nitrogen gas which is a low-activity first reactive gas were fed into the vacuum chamber 2 of the sputtering chamber 1 from the first gas feed opening 15 formed at the front end part of the chimney 9 disposed near the target 4. The flow rates of the argon gas and the nitrogen gas were 20 sccm and 15 sccm, respectively, (where sccm is a unit expressing the gas flow rate supplied in one minute, converted into the volume at 0° C. and 1 atm). The oxygen gas as the second reactive gas was fed from the second gas feed opening 17 formed near the substrate holder 7. The flow rate of oxygen gas was set to 2 sccm. The argon gas sputtered the Ti target 4, and the sputtering particles reacted with the nitrogen gas and the oxygen gas to form the titanium oxynitride film. By feeding the nitrogen gas near the target 4, the electric power coming from the target holder 6 allows the nitrogen gas to be activated, thereby enabling to establish a ready-to-react state. A 1000 W DC power was applied to the target. By adjusting the time of DC power application, the TiON film with 7 nm thickness was manufactured.

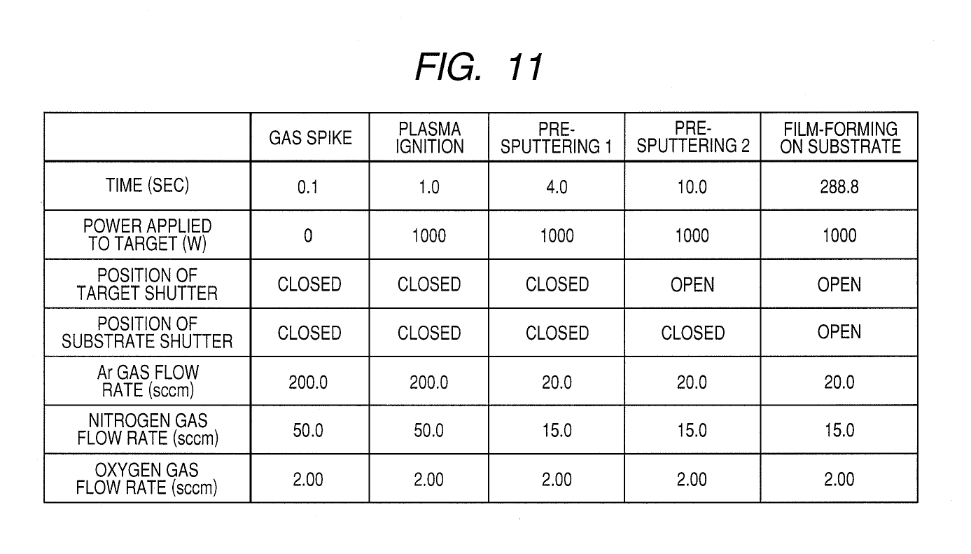

Regarding the step of forming the TiON film (gate electrode film) in Step 5, more detail description will be given below referring to FIG. 11. FIG. 11 illustrates the procedure of forming the gate-electrode film 904 using the sputtering chamber 1. In concrete terms, there are given the time for each treatment step, the power applied to the target, the position of target shutter 14, the position of substrate shutter 19, the argon gas flow rate, the nitrogen gas flow rate, and the oxygen gas flow rate.

The steps of film-forming will be described below referring to FIG. 11.

First, gas-spike is executed. The step increases the internal pressure of the vacuum chamber 2 to create an atmosphere for easily beginning the discharge in the succeeding plasma-ignition step. The condition is in “closed” state of the target shutter 14 and the substrate shutter 19, the flow rate of argon gas is 200 sccm, the flow rate of nitrogen gas is 50 sccm, and the flow rate of oxygen gas is 2 sccm. That is, a control apparatus (not shown) conducts control of the target shutter driving mechanism 33 and the substrate shutter driving mechanism 20, thus to bring the garget shutter 14 and the substrate shutter 19 to “closed” state. In addition, the control apparatus conducts control of each mass-flow controller to feed the argon gas at 200 sccm of flow rate and the nitrogen gas at 50 sccm of flow rate from the first gas feed opening 15, and to feed the oxygen gas at 2 sccm of flow rate from the second gas feed opening 17. By the procedure, the pressure of argon gas near the target 4 increases, and the pressure of the reactive gas is brought to a lower level than the pressure of the argon gas. The ratio of the total flow rate of the first reactive gas and the second reactive gas to the total flow rate of the process gas, (total flow rate of the argon gas, the first reactive gas, and the second reactive gas), supplied to the vacuum chamber 2 is preferably 30% or less to bring the target surface to a metal-mode in the succeeding plasma-ignition step.

Next, the plasma-ignition step is executed. A power of 1000 W DC is applied to the Ti target 4 to generate plasma (plasma ignition) while keeping the position of each shutter and the condition of each gas. The gas condition can prevent the plasma-generation failure which is likely to occur under a low pressure. Preferably by selecting the condition of reactive gas flow rate so as to bring the target surface to a metal-mode, there can be prevented the formation of oxide, nitride, or oxynitride on the surface of the target 4 by the reactive gas. The detail condition to bring the face of the target 4 to the metal-mode is preferably that the ratio of the total flow rate of the reactive gases (first reactive gas and second reactive gas) to the total flow rate of process gas of the reactive gases (first reactive gas and second reactive gas) and the argon gas is 30% or less. From the similar point of view, the power applied to the target is preferably 500 W or more.

Next, the pre-sputtering 1 is executed. In the pre-sputtering 1, the gas condition is changed to 20 sccm for argon, 15 sccm for nitrogen, and 2 sccm for oxygen, while keeping the target power. That is, the control apparatus (not shown) conducts control of each mass-flow controller to feed argon at 20 sccm, and nitrogen at 15 sccm from the first gas feed opening 15, and to feed oxygen gas at 2 sccm from the second gas feed opening 17. The procedure can assure the state without losing the plasma.

According to this example, by the target shutter 14, the space including the target holder 6 (target 4) and the first gas feed opening 15 can be cut off from the space including the substrate holder 7 (substrate 10) and the second gas feed opening during the step of pre-sputtering 1. Accordingly, on sputtering the target 4 and on activating the nitrogen as the first reactive gas, there can be suppressed the arrival of the oxygen as the highly reactive second reactive gas at near the substrate holder 6 being applied with power. As a result, the plasma generated from the substrate holder 6 can activate the low-reactivity nitrogen, and the action of the plasma to the oxygen not wanted to be excessively activated can be decreased.

Then, pre-sputtering 2 is executed. In the step of pre-sputtering 2, the target shutter 14 is opened while keeping the target power, the gas condition, and the “closed” state of the substrate shutter 19. A control apparatus (not shown) conducts control of the target shutter driving mechanism 33 to bring the target shutter 14 to “open” state. The state brings the sputtering particles coming from the Ti target 4 react with oxygen and nitrogen as the reactive gases. By bringing the oxynitride film to adhere to the inner wall of the vacuum chamber 2 including an inner wall of the shield 40, there can be prevented abrupt change in the gas condition in the vacuum chamber 2 during transition to the next substrate film-forming step. By preventing abrupt change of the gas condition in the vacuum chamber 2, the film-formation in the succeeding substrate film-forming step can be done stably from the beginning of the step. In particular, when the interface characteristics are important in the manufacturing of gate stack, such as the case of depositing the gate electrode on the gate insulation film, significant improvement is attained in the device characteristics and in the stability of manufacture of device in the device manufacturing steps.

Next, the film-forming on the substrate is carried out. In the step of substrate film-forming, the substrate shutter 19 is opened while keeping the target electric power, the gas condition, and the position of the target shutter 14. That is, the control apparatus (not shown) conducts control of the substrate shutter driving mechanism 20 to bring the substrate shutter 19 to “open” state. By the procedure, the mechanism of cutting off between the substrate 10 and the target 4 is removed, and thus there begins the deposition of oxynitride film (TiON film) as the gate electrode film 904 on the substrate 10. Although the time necessary for each step of the above procedure is set to an optimum value, the example adopted 0.1 sec for the gas spike, 1 sec for the plasma ignition, 4 sec for the pre-sputtering 1, 10 sec for the pre-sputtering 2, and 288.8 sec for the substrate film-forming.

Through the above procedure, a TiON film with 7 nm of thickness was manufactured.

The condition of the magnetron discharge for sputtering the target material is preferably a very low pressure discharge at lower than 0.1 Pa. Generally to dissociate a low-reactivity gas such as nitrogen, preferably the electron temperature of plasma is high. If the discharge pressure is less than 0.1 Pa, the electron temperature becomes sufficiently high. The lower limit of the discharge pressure is not limited if only the pressure allows discharging.

It is preferable not to spread discharge of high electron temperature activating the gas to near the substrate 10. Accordingly, it is preferable to limit the magnetic field effective for magnetron discharge near the target 4. With the same reason, it is preferable that the distance between the target 4 and the substrate 10 is as large as possible.

### Example 2

Different from Step 5 of Example 1, Example 2 sets the flow rate of oxygen gas fed from the gas feed opening 17 formed near the substrate holder to 3 sccm. Other conditions of the process were the same as those in Example 1, and thus a TiON film with 7 nm in thickness was manufactured.

### Comparative Example 1

Different from Step 5 of Example 1, Comparative Example 1 fed only argon gas from the first gas feed opening 15 formed at front end part of the chimney 9, while feeding oxygen gas at 3 sccm of flow rate and nitrogen gas at 15 sccm of flow rate from the second gas feed opening 17 formed near the substrate holder 7. Other conditions of the process were the same as those in Example 1, and thus a TiON film with 7 nm in thickness was manufactured.

### Comparative Example 2

Different from Step 5 of Example 1, Comparative Example 2 did not use the second gas feed opening 17 formed near the substrate holder 7, and fed oxygen gas at 3 sccm of flow rate, nitrogen gas at 15 sccm of flow rate, and argon gas at 20 sccm of flow rate from the first gas feed opening 15 formed at front end part of the chimney 9. Other conditions of the process were the same as those in Example 1, and thus a TiON film with 7 nm in thickness was formed.

Through the above steps, a stack structure having a Si semiconductor, a high permittivity film, and a metal gate electrode film was formed.

FIG. 10 is a graph illustrating an evaluation result of the oxygen concentration distribution in the depth direction of the gate-stack structure formed by the above procedure using XPS (X-ray photoelectron spectroscopy). The oxygen on the surface of the film is formed by oxidation of the surface when the substrate is exposed to atmospheric air after film-forming, and the oxygen does not affect the characteristics of the semiconductor element.

The TiON film in Comparative Example 1 contains oxygen over 40% of quantity, and thus the film has no sufficient function as the gate electrode.

The TiON film in Comparative Example 2 contains oxygen over 50% of quantity, and thus the film has no sufficient function as the gate electrode.

On the other hand, the TiON film prepared in Example 1 (oxygen flow rate of 2 sccm during sputtering) has an oxygen concentration of about 1%, which considerably suppresses the inclusion concentration of oxygen compared with Comparative Examples. Furthermore, the TiON film prepared in Example 2 (oxygen flow rate of 3 sccm during sputtering) has an oxygen concentration of about 5%, which considerably suppresses the inclusion concentration of oxygen compared with Comparative Examples.

As described above, when the method and the apparatus of the present invention were used, and when the TiON film was used as the electrode film on the high permittivity film, the controllability of the ratio of oxygen to nitrogen was improved. In addition, controlling the ratio of oxygen to nitrogen in TiON allowed controlling the work function value of the TiON film to a desired value. Furthermore, it was found that the reproducibility is superior in relation to the residual oxygen in background and small quantity of oxygen feeding which is likely to become instable owing to easy gettering characteristic.

### Example 3

Example 3 adopted the method of manufacturing the gate stack structure illustrated in FIG. 7. In the example 3, the case that the applied method and apparatus wherein argon gas and nitrogen gas are fed from the first gas feed opening 15 formed near the target 4, while feeding an oxygen gas having higher reactivity than that of the nitrogen gas from the second gas feed opening 17 formed at a position with a distance from the target 4 larger than that of the first gas feed opening 15, are used to form the high permittivity film 903, is explained.

FIG. 12 is the process flow diagram illustrating an example 3 of the method of manufacturing a semiconductor device having the gate-stack structure given in FIG. 7.

In Step S21, the semiconductor substrate 901 is carried in from the load-lock chamber 801 to the manufacturing apparatus 800. In Step S22, the transfer robot of the transfer chamber 802 transfers the semiconductor substrate 901 from the load-lock chamber 801 to the oxidation process chamber 803 without exposing the substrate 901 to atmospheric air, where the interface layer 902 made of silicon oxide, SiO₂, is formed on the surface of the semiconductor substrate 901 by the thermal oxidation process. The process is not necessarily limited to the thermal oxidation, and other film-forming process such as ALD, or plasma oxidation process may be applied.

In Step S23, the high permittivity film 903 is formed on the upper face of the interface layer 902. In Step S23, the transfer robot transfers the semiconductor substrate 901 on which the interface layer 902 has been formed to the sputtering chamber 804, where a high permittivity film made of HfON is formed on the upper face of the interface layer 902 by the reactive sputtering method. The applied sputtering chamber 804 has the same structure as that of the sputtering apparatus 1 given in FIG. 1. In concrete terms, in Step S23, Hf was prepared as the target material, and the HfON film was formed by the sputtering method in an atmosphere of argon gas, nitrogen gas, and oxygen gas under the condition of 600 W of the Hf target power, 12 sccm of the argon gas flow rate, 1.5 sccm of the nitrogen gas flow rate, and 1 sccm of the oxygen gas flow rate.

Both the argon gas and the nitrogen gas as a low-activity reactive gas were fed from the gas feed opening (corresponding to the gas feed opening 15 of the sputtering apparatus 1) formed at front end part of the chimney disposed near the target into the vacuum chamber (corresponding to the vacuum chamber 2 of the sputtering apparatus 1). The oxygen gas as a high-activity reactive gas was fed from the gas feed opening (corresponding to the gas feed opening 17 of the sputtering apparatus 1) positioned near the substrate holder.

In Step S24, the transfer robot transfers the semiconductor substrate 901 on which the high permittivity film 903 has been formed in Step S23 to the sputtering apparatus 1. Titanium is prepared as the target material for the target 4. The sputtering apparatus 1 forms the TiON film as the gate electrode film 904 by the sputtering method in an atmosphere of argon gas, nitrogen gas, and oxygen gas. Both the argon gas and the nitrogen gas as a low-activity reactive gas are fed into the vacuum chamber 2 from the gas feed opening 15 formed at front end part of the chimney 9 disposed near the target 4. The oxygen gas as a high-activity reactive gas is fed from the gas feed opening 17 positioned near the substrate holder 7. The condition of forming TiON is the same as that of Example 1.

Through the above procedure, the semiconductor device having the manufactured gate stack structure improved the controllability of composition of the HfON film, and thus a good quality high permittivity film with EOT 1.4 nm was stably manufactured while suppressing the leak current.

The embodiment conducted experiment using the sputtering apparatus 1 with 240 mm of T/S distance. However, the present invention is not limited to the distance. Nevertheless, the present invention is specifically effective at 100 mm or larger T/S distance. The reason is described in the following. That is, the process chamber normally contains residual oxygen gas. The residual oxygen reacts with the sputtering particles. When T/S distance increased, the probability of occurrence of reaction between the sputtering particles emitted from the target and the residual oxygen increases, which likely increases the inclusion concentration of oxygen also in the formed film. To this point, use of the manufacturing method according to the present invention increases the T/S distance, which is specifically effective to improve the issue of significantly increasing oxygen inclusion.

According to the embodiment, Ti or Hf was used as the target 4 to form an oxynitride film of Ti or Hf on the surface of the substrate 10. The present invention, however, does not limit to the above application, and the present invention can be applied to form a metal oxynitride film such as that of Si, Zr, Al, La, Co, Fe, Ni, B, Mg, Ta, and other elements.

According to the embodiment, nitrogen was used as the first reactive gas, and oxygen was used as the second reactive gas. The present invention is, however, not limited to those ones, and for example, methane gas, propane gas, and the like can be used as the first reactive gas.

1. A method of manufacturing a semiconductor device comprising the steps of:
placing a substrate on a substrate holder in a process chamber; and
sputtering a target in the process chamber by applying electric power thereto while feeding a first reactive gas and a second reactive gas into the process chamber, and making particles of a target material generated by the sputtering react with the first reactive gas and the second reactive gas, to form a film containing the target material on the substrate, the film being generated by the reaction, wherein
the second reactive gas is higher than the first reactive gas with respect to reactivity to a surface of the target, the particles of the target material, or the formed film, and
the step of forming a film is conducted by feeding at least the first reactive gas from a first gas feed opening formed near the target, and by feeding the second reactive gas from a second gas feed opening formed at a position with the distance from the target larger than that of the first gas feed opening.

2. A method of manufacturing a semiconductor device according to claim 1, wherein the second gas feed opening is formed near the substrate holder.

3. A method of manufacturing a semiconductor device according to claim 1, wherein a magnetic field is formed near the target.

4. A method of manufacturing a semiconductor device according to claim 1, wherein the target is made of the one selected from the group consisting of Ti, Ta, Hf, Zr, Si, La, Co, Fe, Ni, B, Mg and AI.

5. A method of manufacturing a semiconductor device according to claim 1, wherein the first reactive gas is a gas containing nitrogen, and the second reactive gas is a gas containing oxygen.

6. A method of manufacturing a semiconductor device according to claim 1, wherein the step of forming a film is conducted by further feeding an inert gas from the first gas feed opening.

7. A method of manufacturing a semiconductor device according to claim 6, further comprising the step of igniting plasma, before the step of forming a film, by feeding the inert gas and the first reactive gas from the first gas feed opening, and by feeding the second reactive gas from the second gas feed opening, while shielding between the target and the substrate using an openable and closable shutter, wherein the flow rate of the fed inert gas is larger than that of the inert gas fed in the step of forming a film.

8. A method of manufacturing a semiconductor device according to claim 7, wherein the ratio of the total flow rate of the first reactive gas and the second reactive gas to the total flow rate of the inert gas, the first reactive gas, and the second reactive gas, is 30% or less in the step of igniting plasma.

9. A method of manufacturing a semiconductor device according to claim 8, wherein the electric power applied to the target is 500 W or more in the step of igniting plasma.

10. A method of manufacturing a semiconductor device according to claim 1, further comprising the step of, before the step of forming a film, forming a film in the process chamber, under the same condition as that in the step of forming a film, while shielding between the target and the substrate using an openable and closable shutter.

11. A method of manufacturing a semiconductor device according to claim 1, wherein the step of forming a film is a step of forming a gate electrode film on a gate insulation film.

12. A sputtering apparatus comprising:
a process chamber;
a target holder provided in the process chamber for holding a target;
a voltage-supply mechanism for applying a specified voltage to the target holder;
a magnetic-field forming mechanism to form a magnetic field near the target holder;
a substrate holder provided in the process chamber for holding a substrate:
a first gas feed opening formed near the target holder for feeding a first reactive gas into the process chamber; and
a second gas feed opening formed at a position with the distance from the target holder larger than that of the first gas feed opening, for feeding a second reactive gas into the process chamber, wherein
the second reactive gas is higher than the first reactive gas with respect to reactivity to a surface of the target, the particles of the target material, or the formed film, and
the sputtering apparatus is configured so that the specified voltage is applied to the target holder by the voltage-supply mechanism to sputter the target, particles of a target, material generated by the sputtering reacts with the first reactive gas fed from the first gas feed opening and the second reactive gas fed from the second gas feed opening, and a film containing the target material, the film being generated by the reaction, is formed on the substrate held on the substrate holder.

13. A sputtering apparatus according to claim 12, further comprising
a substrate holder provided in the process chamber for placing the substrate thereon, wherein
the second gas feed opening is formed near the substrate holder.

14. A sputtering apparatus according to claim 12, further comprising
a cylindrical shield surrounding the target holder, wherein
the first gas feed opening is formed at an opened front end part of the cylindrical shield.

15. A sputtering apparatus according to claim 12, further comprising
a shutter which can shield between the target holder and the second gas feed opening.
